(19) United States
(12) Patent Application Publication
(10) Pub. No.: US 2026/0123104 A1
(43) Pub. Date: Apr. 30, 2026

(54) LIGHT-EMITTING DIODE AND LIGHT-EMITTING DEVICE

(71) Applicant: Tianjin Sanan Optoelectronics Co., Ltd., Tianjin (CN)

(72) Inventors: Fulong Li, Tianjin (CN); Jindong Wei, Tianjin (CN); Hanxin Liu, Tianjin (CN); Liwei Wang, Tianjin (CN)

(21) Appl. No.: 19/370,801

(22) Filed: Oct. 28, 2025

(30) Foreign Application Priority Data
Oct. 29, 2024 (CN) 202411516634.2

(51) Int. Cl. H10H 20/812

(52) U.S. Cl. CPC H10H 20/812

(57) ABSTRACT

A light-emitting diode is provided, at least including a semiconductor stack layer. The semiconductor stack layer has a first surface and a second surface opposite to each other, and includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. An emission wavelength of the light-emitting diode is in a range of 605 nm to 730 nm. A number of the multiple periods of the multiple quantum well structure in the active layer is in a range of 5 to 25, and a thickness of the barrier layer is less than or equal to 100 Å.

### CROSS-REFERENCE TO RELATED APPLICATION

This application claims priority to Chinese Patent Application No. 202411516634.2, filed on October 29, 2024, which is herein incorporated by reference in its entirety.

### TECHNICAL FIELD

The disclosure relates to the field of semiconductor manufacturing technologies, and more particularly to a light-emitting diode and a light-emitting device.

### BACKGROUND

Light-emitting diodes (LEDs) have advantages such as high luminous intensity, high efficiency, small size, and long service life, and are considered one of the most promising light sources currently. In recent years, LEDs have been widely used in daily life, for example, in the fields of lighting, signal displays, backlight sources, vehicle lights, and large-screen displays. Meanwhile, these applications have also placed higher demands on the brightness and luminous efficiency of LEDs.

In response to a growing demand in the high-performance automotive LED market, hot/cold factor (HC) of an LED chip has become a key indicator for measuring market competitiveness and applicability of the LED chip. The HC performance is directly related to the operational efficiency and stability of the LED under extreme temperature conditions, and is an important consideration for many automotive manufacturers when selecting LED light sources.

In order to enhance the HC performance of the LED chip, common technical approaches in the industry include increasing the number of multiple quantum well (MQW) pairs or increasing a thickness of a barrier layer. These improvements have been proven in practical applications to effectively reduce carrier overflow and enhance the HC performance. However, these solutions also have a drawback, that is, a voltage of the chip increases significantly in low-temperature environments, and a voltage difference between low temperature and room temperature is too large, even exceeding a specific threshold, failing to meet the reliable operation requirements of LED devices under extreme climatic conditions.

Therefore, it is indeed necessary to provide an improved technical solution that addresses the shortcomings of the aforementioned related art.

### SUMMARY

In view of the above defects and disadvantages in the related art, an objective of the disclosure is to provide a light-emitting diode and a light-emitting device, which can achieve good HC performance while effectively controlling and reducing a voltage increase in low-temperature environments, thereby achieving an optimal balance between the HC performance and low-temperature voltage characteristics.

According to an aspect of the disclosure, a light-emitting diode is provided, and at least includes a semiconductor stack layer. The semiconductor stack layer has a first surface and a second surface opposite to each other, and the semiconductor stack layer includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. An emission wavelength of the light-emitting diode is in a range of 605 nanometers (nm) to 730 nm. A number of the multiple periods of the multiple quantum well structure in the active layer is in a range of 5 to 25, and a thickness of the barrier layer is in a range of 50 angstroms (Å) to 100 Å.

According to an aspect of the disclosure, a light-emitting diode is provided, and at least includes a semiconductor stack layer. The semiconductor stack layer has a first surface and a second surface opposite to each other, and the semiconductor stack layer includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. In a characteristic band, a maximum number of the multiple periods in the active layer decreases as an emission wavelength of the light-emitting diode increases, and a wavelength of the characteristic band is in a range of 605 nm to 730 nm.

According to an aspect of the disclosure, a light-emitting diode is provided, and at least includes a semiconductor stack layer. The semiconductor stack layer has a first surface and a second surface opposite to each other, and the semiconductor stack layer includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. In a characteristic band, a thickness of the barrier layer decreases as an emission wavelength of the light-emitting diode increases, and a wavelength of the characteristic band is in a range of 605 nm to 730 nm.

According to an aspect of the disclosure, a light-emitting device is provided, and includes a light-emitting source, and the light-emitting source is any of the light-emitting diodes described in the above technical solutions.

Compared to the related art, the light-emitting diode and the light-emitting device provided by the disclosure have at least the following beneficial effects.

The technical solutions of the disclosure optimize a structure of the active layer according to variations in wavelength across different bands, particularly through adjustment of either the number of periods of the multiple quantum well structure or the thickness of the barrier layer. Within a band of 605 nm to 730 nm, the number of periods of the multiple quantum well structure in the active layer is in a range of 5 to 25, and the thickness of the barrier layer is less than or equal to 100 Å. This addresses the issue where voltage stability deteriorates with increasing emission wavelength, thereby ensuring that the voltage difference of the light-emitting diode between low-temperature and room-temperature remains stable and controllable.

Furthermore, the light-emitting device provided by the disclosure includes the light-emitting diode described in the aforementioned technical solutions. Therefore, the light-emitting device also exhibits the aforementioned advantageous effects, thereby effectively enhancing the HC performance and low-temperature voltage stability of the device.

### BRIEF DESCRIPTION OF DRAWINGS

In order to provide a clearer explanation of technical solutions in the disclosure or related art, drawings required in embodiments or the related art descriptions will be briefly introduced below. Apparently, drawings in the following descriptions are some of the embodiments of the disclosure. For those skilled in the art, other drawing can be obtained according to these drawings without creative work. The positional relationships described in the drawings below, unless otherwise specified, are based on directions indicated by components in the drawings.

For convenience or clarity, a thickness and a size of each layer shown in the drawings can be exaggerated, omitted, or roughly drawn. In addition, the size of the light-emitting device does not fully reflect the actual size.

FIG. 1 illustrates a schematic sectional structural diagram of a semiconductor stack layer provided by the disclosure.

FIG. 2 illustrates a schematic sectional structural diagram of an active layer provided by the disclosure.

FIG. 3 illustrates a schematic sectional structural diagram of a light-emitting diode provided by the disclosure.

FIG. 4 illustrates a schematic sectional structural diagram of another light-emitting diode provided by the disclosure.

FIG. 5 illustrates a schematic structural diagram of a light-emitting device provided by the disclosure.

Description of reference signs:

100-growth substrate; 101-buffer layer; 102-etching stop layer; 103-first ohmic contact layer; 104-first current spreading layer; 105-first covering layer; 106-first spacer layer; 107-active layer; 1071-barrier layer; 1072-well layer; 108-second spacer layer; 109-second covering layer; 110-second current spreading layer; 111-second ohmic contact layer; 112-first surface; 113-second surface; 200-substrate; 201-bonding layer; 202-reflective layer; 203-first electrode; 204-second electrode; 300-light-emitting device; 310-circuit board; 320-light-emitting source.

### DETAILED DESCRIPTION OF EMBODIMENTS

The HC performance characterizes a relationship between the luminous brightness and an operating temperature of a light-emitting diode. Better HC performance indicates superior performance of the light-emitting diode under extreme temperatures. HC can be understood as a thermal attenuation value, for instance, a ratio of luminous intensity of the light-emitting diode at 85 Celsius degrees (℃) to that at 25℃ is defined as a HC parameter of the light-emitting diode under these temperature conditions. LEDs are deployed in diverse application scenarios. When used as vehicle lights outdoors, the ambient temperature can even drop below -40℃. Under such extremely low temperatures, the voltage of the chip increases significantly, thereby potentially leading to excessive power consumption or even device failure (“dead light”). Furthermore, market requirements for brightness attenuation of LED products under both high and low temperatures are increasingly stringent. Related art can no longer meet the demands for reliable operation of LED devices under such extreme climatic conditions.

Based on the above background, the disclosure optimizes an epitaxial structure of LED to provide a light-emitting diode, at least including a semiconductor stack layer. The semiconductor stack layer has a first surface and a second surface opposite to each other, and the semiconductor stack layer includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. An emission wavelength of the light-emitting diode is in a range of 605 nm to 730 nm. A number of the multiple periods of the multiple quantum well structure in the active layer is in a range of 5 to 25, and a thickness of the barrier layer is in a range of 50 Å to 100 Å. In a specific wavelength band, by adjusting the number of periods of the multiple quantum well structure and the thickness of the barrier layer, that is, the number of periods and the thickness of the barrier layer are reduced as the emission wavelength of the light-emitting diode increases across this band, so that a voltage increase in low-temperature environments is effectively controlled and reduced without significantly degrading the HC performance, thereby achieving an optimal balance between the HC performance and low-temperature voltage characteristics.

In some embodiments, the barrier layer includes an aluminum (Al) component, and a content of the Al component in the barrier layer is in a range of 30% to 100%. The content of the Al component in the barrier layer is adjusted to improve band shift of the barrier layer or reduce interlayer lattice defects.

In some embodiments, the number of the multiple periods of the multiple quantum well structure in the active layer is in a range of 7 to 22, and the thickness of the barrier layer is in a range of 60 Å to 90 Å.

In some embodiments, the content of the Al component in the barrier layer is in a range of 55% to 75%.

In some embodiments, the emission wavelength of the light-emitting diode is less than or equal to 625 nm. The number of the multiple periods of the multiple quantum well structure in the active layer is in a range of 8 to 25, and the thickness of the barrier layer is in a range of 70 Å to 100 Å.

In some embodiments, the content of the Al component in the barrier layer is in a range of 50% to 100%.

In some embodiments, the emission wavelength of the light-emitting diode is in a range of 615 nm to 625 nm. The number of the multiple periods of the multiple quantum well structure in the active layer is in a range of 15 to 22, and the thickness of the barrier layer is in a range of 70 Å to 90 Å.

In some embodiments, the content of the Al component in the barrier layer is in a range of 65% to 75%.

In some embodiments, the emission wavelength of the light-emitting diode is greater than or equal to 625 nm. The number of the multiple periods of the multiple quantum well structure in the active layer is in a range of 5 to 15, and the thickness of the barrier layer is in a range of 50 Å to 80 Å.

In some embodiments, the content of the Al component in the barrier layer is in a range of 30% to 80%.

In some embodiments, the emission wavelength of the light-emitting diode is in a range of 625 nm to 635 nm. The number of the multiple periods of the multiple quantum well structure in the active layer is in a range of 7 to 12, and the thickness of the barrier layer is in a range of 60 Å to 70 Å, thereby further optimizing the low-temperature voltage performance of LED with a long wavelength.

In some embodiments, the content of the Al component in the barrier layer is in a range of 55% to 65%.

In some embodiments, the light-emitting diode further includes a first electrode and a second electrode, and the first electrode and the second electrode are electrically connected to the first semiconductor layer and the second semiconductor layer, respectively.

A light-emitting diode at least includes a semiconductor stack layer. The semiconductor stack layer has a first surface and a second surface opposite to each other, and the semiconductor stack layer includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. In a characteristic band, a maximum number of the multiple periods in the active layer decreases as an emission wavelength of the light-emitting diode increases, and a wavelength of the characteristic band is in a range of 605 nm to 730 nm. In a specific wavelength band, by adjusting

the number of periods of the multiple quantum well structure, that is, the number of periods is reduced as the emission wavelength of the light-emitting diode increases across this band, so that the voltage increase in low-temperature environments is effectively controlled and reduced without significantly degrading the HC performance, thereby achieving an optimal balance between the HC performance and the low-temperature voltage characteristics.

In some embodiments, the maximum number of the multiple periods in the active layer varies in a non-arithmetic manner, and a differential in the maximum number of the multiple periods in the active layer increases as the emission wavelength of the light-emitting diode increases. For a band with shorter wavelengths, the multiple quantum well structure with a certain number of periods can ensure stable HC performance of the product. As the emission wavelength increases, the maximum number of periods in the active layer is reduced to a greater extent, so as to mitigate the issue of low-temperature voltage increase.

In some embodiments, in the characteristic band, a thickness of each barrier layer in the active layer is the same or different. The thickness of the barrier layer is optimized and adjusted according to actual needs to meet the performance requirements of different products.

A light-emitting diode at least includes a semiconductor stack layer. The semiconductor stack layer has a first surface and a second surface opposite to each other, and the semiconductor stack layer includes a first semiconductor layer, an active layer and a second semiconductor layer sequentially stacked in that order from the first surface to the second surface. The active layer includes a multiple quantum well structure with multiple periods, and each period of the multiple quantum well structure includes a well layer and a barrier layer sequentially stacked in that order. In a characteristic band, a thickness of the barrier layer decreases as an emission wavelength of the light-emitting diode increases, and a wavelength of the characteristic band is in a range of 605 nm to 730 nm. By adjusting the thickness of the barrier layer, that is, the thickness of the barrier layer is reduced as the emission wavelength increases across this band, so that the voltage increase in low-temperature environments is effectively controlled and reduced without significantly degrading the HC performance, thereby achieving an optimal balance between the HC performance and the low-temperature voltage characteristics.

In some embodiments, the characteristic band includes a first band and a second band in sequence from a low wavelength to a high wavelength, and a critical wavelength value between the first band and the second band is located within a range of 620 nm to 630 nm. A differential in

a maximum number of the multiple periods in the active layer in the second band is greater than a differential in a maximum number of the multiple periods in the active layer in the first band. For a band with longer wavelengths, the number of periods of the multiple quantum well structure and/or the thickness of the barrier layer in the active layer are further reduced, so as to strike a balance between the HC performance, production costs, and low-temperature voltage levels.

In some embodiments, a wavelength of the first band is less than or equal to 625 nm. In the first band, a number of the multiple periods of the multiple quantum well structure in the active layer is in a range of 8 to 25, the thickness of the barrier layer is in a range of 70 Å to 100 Å, and a content of an Al component in the barrier layer is in a range of 50% to 100%.

In some embodiments, a wavelength of the second band is greater than or equal to 625 nm. In the second band, a number of the multiple periods of the multiple quantum well structure in the active layer is in a range of 5 to 15, the thickness of the barrier layer is in a range of 50 Å to 80 Å, and a content of an Al component in the barrier layer is in a range of 30% to 80%.

In some embodiments, a thickness of each well layer in the active layer is in a range of 30 Å to 50 Å.

In some embodiments, a material of the barrier layer is Alₓ₁Ga_{y1}In₁₋_{x1-y1}P, a material of the well layer is Alₓ₂Ga_{y2}In₁₋_{x2-y2}P, where 0≤x2<x1≤1, x1≥0.3, and 0≤y1<y2≤1, which is applicable to the red LED provided in the technical solution of the disclosure, thereby achieving precise control of the emission wavelength of LED.

The disclosure further provides a light-emitting device, and the light-emitting device includes a light-emitting source. The light-emitting source is the light-emitting diode provided by the above technical solutions, and the light-emitting device also has good HC performance and low-temperature voltage performance.

In some embodiments, a difference between a voltage of the light-emitting device under operating conditions of -40℃ or below and a voltage of the light-emitting device at room temperature is less than or equal to 10% of the voltage of the light-emitting device at room temperature, or 0.2 volts (V). The light-emitting device can maintain voltage stability at extremely low temperatures, which meets the reliable operation requirements of the device under extreme weather conditions.

The implementation of the disclosure is illustrated below by specific embodiments. Those skilled in the art can readily understand other advantages and efficacies of the disclosure from the content disclosed in this specification. The disclosure may also be implemented or applied through other different specific embodiments. Various details in this specification may be modified or changed based on different perspectives and applications without departing from a spirit of the disclosure. It should be noted that, in the absence of conflict, the features in the following embodiments and examples may be combined with each other.

A composition and dopants of each layer contained in the light-emitting diode of the disclosure may be analyzed by any suitable method, such as a secondary ion mass spectrometry (SIMS). The thickness of each layer contained in the light-emitting diode of the disclosure may be analyzed by any suitable method, such as a transmission electron microscopy (TEM) or a scanning electron microscopy (SEM), in order to correlate, for example, with the depth position of each layer in a SIMS profile.

### Embodiment 1

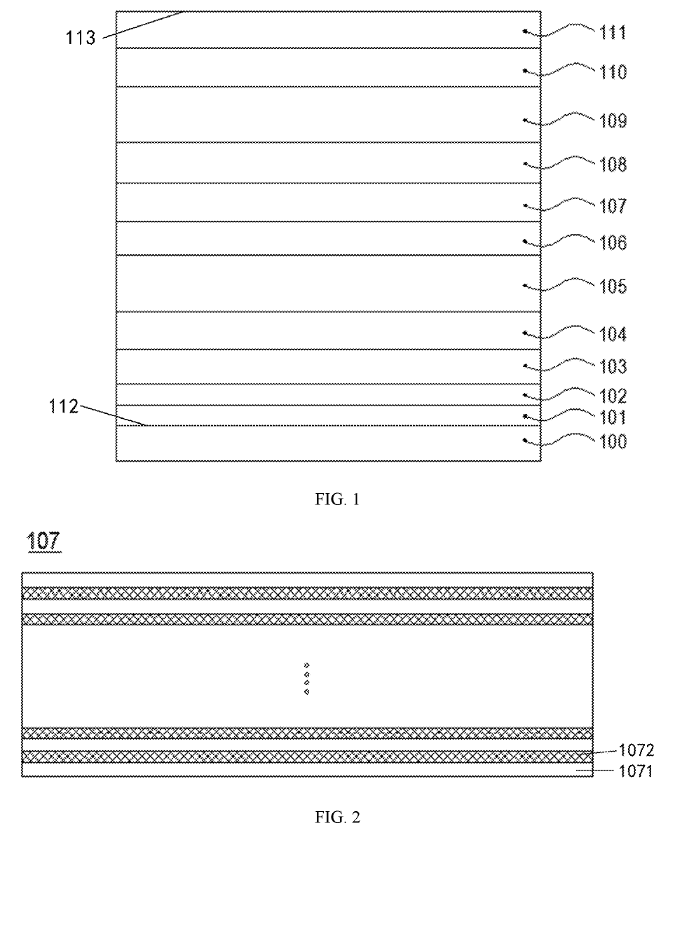

As shown in FIG. 1 and FIG. 2, the embodiment provides an epitaxial structure of a light-emitting diode.

FIG. 1 illustrates a schematic diagram of an epitaxial structure of a light-emitting diode provided in the embodiment. The epitaxial structure includes at least a growth substrate 100 and a semiconductor stack layer located above the growth substrate 100. The semiconductor stack layer has a first surface 112 and a second surface 113 opposite to each other, and the semiconductor stack layer includes a first semiconductor layer, an active layer 107, and a second semiconductor layer sequentially stacked in that order from the first surface 112 to the second surface 113.

Continuing to refer to FIG. 1, the growth substrate 100 includes, but is not limited to, gallium arsenide (GaAs), and other materials, such as gallium phosphide (GaP), and indium phosphide (InP), may also be used. In the embodiment, a GaAs growth substrate 100 is used as an example. In an optional embodiment, a buffer layer 101, an etching stop layer 102, and a first ohmic contact layer 103 are sequentially disposed between the growth substrate 100 and a first current spreading layer 104 in that order. Since crystal lattice quality of the buffer layer 101 is relatively better than that of the growth substrate 100, growing the buffer layer 101 on the growth substrate 100 helps eliminate the impact of lattice defects from the growth substrate 100 on the semiconductor stack layer. The etching stop layer 102 serves as a stop layer for chemical etching in later steps. In an optional embodiment, the etching stop layer 102 is an n-type etching stop layer made of n-gallium indium phosphide (n-GaInP). In order to facilitate subsequent removal of the growth substrate 100, a thickness of the growth substrate 100 is controlled within 500 nm or within 200 nm. In an optional embodiment, the first ohmic contact layer 103 is made of a GaAs material, with a thickness ranging from 10 nm to 100 nm and a doping concentration of 1×10¹⁸/cm³ to 1×10¹⁹/cm³, in an embodiment, 2×10¹⁸/cm³, to achieve better ohmic contact results.

Continuing to refer to FIG. 1, the semiconductor stack layer has a first surface 112 and a second surface 113 opposite to each other, and the semiconductor stack layer includes a first semiconductor layer, an active layer 107, and a second semiconductor layer stacked sequentially in that order from the first surface 112 to the second surface 113. The first semiconductor layer and the second semiconductor layer can provide electrons or holes through n-type or p-type doping, respectively. The n-type semiconductor layer can be doped with n-type dopants such as silicon (Si), germanium (Ge), or tin (Sn), and the p-type semiconductor layer can be doped with p-type dopants such as magnesium (Mg), zinc (Zn), calcium (Ca), strontium (Sr), carbon (C), or barium (Ba). When the first semiconductor layer is an n-type semiconductor, the second semiconductor layer is a p-type semiconductor layer; and when the first semiconductor layer is a p-type semiconductor layer, the second semiconductor layer is an n-type semiconductor layer. The first semiconductor layer, the active layer 107, and the second semiconductor layer can be specifically made of materials such as aluminum gallium indium nitride (AlGaInN), gallium nitride (GaN), aluminum gallium nitride (AlGaN), aluminum indium phosphide (AlInP), aluminum gallium indium phosphide (AlGaInP), GaAs, or aluminum gallium arsenide (AlGaAs). The embodiment uses the first semiconductor layer as an n-type semiconductor layer for detailed description.

Each layer of the semiconductor stack layer can be formed on the growth substrate 100 by methods such as physical vapor deposition (PVD), chemical vapor deposition (CVD), epitaxy growth technology, or atomic layer deposition (ALD). The semiconductor stack layer is a semiconductor material capable of providing conventional radiation such as ultraviolet, blue, green, yellow, red, and infrared light. By adjusting a composition ratio of the semiconductor material in the active layer 107, light with a target wavelength is emitted, thereby making an emission band fall between 200 nm and 950 nm. For example, a gallium nitride-based (GaN-based) semiconductor stack layer doped with elements such as Al and indium (In) mainly provides radiation in a band of 200 nm to 550 nm; or an aluminum gallium indium phosphide-based (AlGaInP-based) or aluminum gallium arsenide-based (AlGaAs-based) semiconductor stack layer mainly provides radiation in a band of 550 nm to 950 nm. The light-emitting diode provided in the embodiment is a red LED with an emission wavelength in a range of 600 nm to 650 nm.

Continuing to refer to FIG. 1, the first semiconductor layer includes a first covering layer 105 that provides electrons to the active layer 107, for example, made of AlGaInP. In order to improve the uniformity of current spreading, the first semiconductor layer may also include a first current spreading layer 104, for example, made of AlGaInP, with a thickness of 2500 nm to 4000 nm. In order to prevent dopants from the first cladding layer 105 from diffusing into the active layer 107 and affecting the crystal quality of the active layer 107, a first spacer layer 106 may also be disposed between the first covering layer 105 and the active layer 107. It can be understood that the first semiconductor layer may also be configured with layers other than those mentioned above, and some layers may also be omitted.

Referring to FIG. 1 and FIG. 2, the active layer 107 is a region where electrons and holes recombine to provide optical radiation. It includes a multiple quantum well structure with multiple periods, and each period of the multiple quantum well structure includes a well layer 1072 and a barrier layer 1071 stacked sequentially in that order, with the barrier layer 1071 having a larger band gap than the well layer 1072. In the embodiment, a material of the barrier layer 1071 is Alₓ₁Ga_{y1}In_{1-x1-y1}P, and a material of the well layer 1072 is Alₓ₂Ga_{y2}In_{1-x2-y2}P, where 0 ≤ x2 < x1 ≤ 1, and 0 ≤ y1 < y2 ≤ 1. This is suitable for the red LED provided in the technical solution of the disclosure, thereby enabling precise control of the emission wavelength of LED and allowing the active layer 107 to emit red light with a wavelength of 550 nm to 750 nm. In an optional embodiment, the material of the well layer 1072 is gallium indium phosphide (GaInP) to improve the aging stability of the component. As the Al component in the barrier layer 1071 increases, the band gap widens, thereby causing the emission wavelength to shift towards shorter wavelengths. However, excessively high Al component leads to more defects and stress within the material, thereby reducing the lifetime and reliability of the device. In an embodiment, a content of the Al component in the barrier layer 1071 is in a range of 30% to 100%, that is, 0.3 ≤ x1 ≤ 1, to achieve a balance between the various performance aspects of the device mentioned above.

In a characteristic band, a maximum number of periods in the active layer 107 decreases as the emission wavelength of the light-emitting diode increases. A wavelength of the characteristic band is in a range of 605 nm to 730 nm. By adjusting the number of periods of the multiple quantum well structure, that is, the number of periods is reduced as the emission wavelength increases within the above band, for example, from the existing 25 or more to 15 or even fewer, so that the voltage increase in low-temperature environments is effectively controlled and reduced without significant degradation in the HC performance, thereby achieving an optimal balance between the HC performance and the low-temperature voltage characteristics. It is understandable that as temperature changes, carrier mobility also changes. Under extremely low-temperature conditions, the carrier mobility significantly decreases. When the number of periods of the multiple quantum well structure remains unchanged, more carriers may be captured or recombine at non-radiative centers during transport, thereby reducing the number of carriers reaching an effective light-emitting region. In order to maintain the same luminous intensity, the voltage needs to be increased to drive more carrier migration. In the aforementioned characteristic band, longer wavelengths require less band gaps, and the energy required for recombination is relatively lower. Therefore, the voltage change is more significantly affected by temperature. Reducing the number of periods of the multiple quantum well structure as the emission wavelength increases can effectively control the voltage fluctuation of the components in low-temperature environments. In an embodiment, the wavelength of the characteristic band is in a range of 615 nm to 635 nm.

In an optional embodiment, the maximum number of periods in the active layer 107 varies in a non-arithmetic manner, and a differential in the maximum number of periods gradually increases as the emission wavelength of the light-emitting diode increases. For example, for the bands of 600 nm to 615 nm and 615 nm to 625 nm, the maximum number of periods in the active layer 107 only needs to be reduced by 2 or less sequentially, whereas for bands above 625 nm, the maximum number of periods needs to be reduced by 5 or more to meet the requirements for low-temperature voltage stability. For the band with shorter wavelengths, the multiple quantum well structure with a certain number of periods ensures stable HC performance of the product. However, as the emission wavelength increases, the maximum number of periods in the active layer 107 is reduced more significantly to mitigate the issue of low-temperature voltage increase. In an embodiment, the thickness of each barrier layer 1071 in the active layer 107 may be the same or different, which can be optimized and adjusted according to the performance requirements of different products. In an optional embodiment, the thickness of each barrier layer 1071 in the active layer 107 is the same, which helps improve the consistency and reliability of LED manufacturing. The thickness of the barrier layer 1071 may also be set differently for one or some layers to adjust the energy band structure and density of states in the quantum wells, so as to further optimize the luminous performance to meet different product requirements. The more the number of periods in the active layer 107 falls within the specified range, the better the HC performance of the light-emitting diode. Appropriately reducing the number of periods in the active layer 107 not only balances the issue of low-temperature voltage stability but also saves production costs. The appropriate active layer structure can be selected based on the actual performance requirements of products in different wavelength bands.

In an optional embodiment, the characteristic band sequentially includes a first band and a second band from a lower wavelength to a higher wavelength. A critical wavelength value between the first band and the second band is located within a range of 620 nm to 630 nm. The differential in the maximum number of periods in the active layer 107 within the second band is greater than that within the first band. For the band with longer wavelengths, the number of periods of the multiple quantum well structure in the active layer 107 is further reduced to balance the HC performance, the production costs, and the low-temperature voltage performance. In an embodiment, the critical wavelength value is 625 nm. That is, for light-emitting diodes with wavelengths above 625 nm, the maximum number of periods in the active layer 107 decreases more significantly as the emission wavelength increases, so as to effectively address the issue of low-temperature voltage increase. For light-emitting diodes with wavelengths below 625 nm, the maximum number of periods in the active layer 107 does not need to be reduced excessively to balance the HC performance and the issue of low-temperature voltage increase. In an optional embodiment, a thickness of the well layer 1072 is in a range of 30 Å to 50 Å, and the thickness of the barrier layer 1071 also decreases as the emission wavelength of the light-emitting diode increases. For light-emitting diodes in each wavelength band, the thickness of each barrier layer 1071 may be the same or different.

In an optional embodiment, the wavelength of the first band is less than or equal to 625 nm. In the first band, the number of periods of the multiple quantum well structure in the active layer 107 is in a range of 8 to 25, the thickness of the barrier layer 1071 is less than or equal to 90 Å, and the thickness of the well layer 1072 is in a range of 30 Å to 50 Å. In an embodiment, the number of periods of the multiple quantum well structure is in a range of 15 to 22, the thickness of the barrier layer 1071 is in a range of 70 Å to 90 Å, and the thickness of the well layer 1072 is 40 Å. For light-emitting diodes with shorter emission wavelengths within the characteristic band, the decrease in operating temperature has a relatively smaller impact on carrier mobility, and the resulting voltage increase is also relatively smaller. Appropriately reducing the number of periods of the multiple quantum well structure can balance the HC performance and the low-temperature voltage issues. Concurrently, controlling the thickness of the barrier layer 1071, for example, by correspondingly reducing the thickness, product performance is further optimized.

Specifically, the first band further includes a first sub-band and a second sub-band, and a critical wavelength value between the first sub-band and the second sub-band is approximately at 615 nm. The embodiment uses 615 nm as the critical wavelength value. A wavelength of the first sub-band is in a range of 600 nm to 615 nm, and a wavelength of the second sub-band is in a range of 615 nm to 625 nm. For light-emitting diodes in the first sub-band, the number of periods of the multiple quantum well structure in the active layer 107 is in a range of 8 to 25, and the thickness of the barrier layer 1071 is in a range of 70 Å to 100 Å. In an embodiment, the number of periods in the active layer 107 is in a range of 18 to 20, for example, 18, 19, or 20, and the thickness of the barrier layer 1071 is in a range of 80 Å to 90 Å. For light-emitting diodes in the second sub-band, the number of periods of the multiple quantum well structure in the active layer 107 is in a range of 8 to 20, and the thickness of the barrier layer 1071 is in a range of 70 Å to 90 Å. In an embodiment, the number of periods in the active layer 107 is in a range of 16 to 20, for example, 16 or 18, and the thickness of the barrier layer 1071 is in a range of 70 Å to 80 Å. For light-emitting diodes emitting within the first band, balancing the HC performance and the low-temperature voltage performance can be largely achieved solely by adjusting the number of periods of the multiple quantum well structure, while the thickness of the barrier layer 1071 may remain unchanged.

In an optional embodiment, the wavelength of the second band is greater than or equal to 625 nm. In the second band, the number of periods of the multiple quantum well structure in the active layer 107 is in a range of 5 to 15, the thickness of the barrier layer 1071 is in a range of 50 Å to 80 Å, and the thickness of the well layer 1072 is in a range of 30 Å to 50 Å. In an embodiment, the number of periods of the multiple quantum well structure is in a range of 7 to 12, the thickness of the barrier layer 1071 is in a range of 60 Å to 70 Å, and the thickness of the well layer 1072 is 40 Å. For light-emitting diodes with longer emission wavelengths within the characteristic band, the decrease in operating temperature has a more pronounced impact on carrier mobility, and the resulting voltage increase is also relatively larger. For instance, in a -40°C operating environment, the voltage difference compared to room temperature can even exceed 10%. Reducing the number of periods of the multiple quantum well structure to no more than 15, or even no more than 12, is necessary to balance the HC performance and the low-temperature voltage issues. Concurrently, the thickness of the barrier layer 1071 is controlled and significantly reduced to ensure a sufficient number of carriers recombine in the well layer 1072s, thereby maintaining product brightness and further optimizing product performance.

As an example, for light-emitting diodes with wavelengths of 600 nm, 615 nm, 625 nm, and 635 nm, the number of periods of their multiple quantum well structures can be set to 21, 20, 18, and 10, respectively.

Continuing to refer to FIG. 1, the second semiconductor layer is located above the active layer 107. The second semiconductor layer includes a second covering layer 109 that provides holes to the active layer 107, for example, made of AlGaInP. In order to improve the uniformity of current spreading, the second semiconductor layer may also include a second current spreading layer 110, with a thickness of 2500 nm to 4000 nm. In order to prevent dopants from the second covering layer 109 from diffusing into the active layer 107 and affecting its crystal quality, the embodiment may also include a second spacer layer 108 disposed between the second covering layer 109 and the active layer 107. The second semiconductor layer may also be configured with layers other than those mentioned above, and some layers may be omitted.

### Embodiment 2

Referring to FIG. 1 and FIG. 2, the embodiment also provides an epitaxial structure of a light-emitting diode. Descriptions of parts that are the as or similar to those in the embodiment 1 are omitted here. The difference from the embodiment 1 is as follows. The active layer 107 includes a multiple quantum well structure with multiple periods, and each period includes a well layer 1072 and a barrier layer 1071 stacked sequentially in that order. The barrier layer 1071 has a larger band gap than the well layer 1072. In a characteristic band, a thickness of the barrier layer 1071 decreases as an emission wavelength of the light-emitting diode increases. A wavelength of the characteristic band is in a range of 600 nm to 650 nm. By adjusting the thickness of the barrier layer 1071, that is, the thickness of the barrier layer 1071 is reduced as the emission wavelength increases within this band, for example, from 90 Å or thicker down to 60 Å or thinner, so that the voltage increase in low-temperature environments can be effectively controlled and reduced without significant degradation in HC performance, thereby achieving an optimal balance between the HC performance and the low-temperature voltage characteristics, and meeting product application requirements. In an embodiment, the wavelength of the characteristic band is in a range of 615 nm to 635 nm.

It is understandable that the carrier mobility changes with temperature. Under extremely low-temperature conditions, the carrier mobility decreases significantly. When the thickness of the barrier layer 1071 remains unchanged, more carriers may be unable to tunnel through, thereby reducing the number of carriers reaching the effective light-emitting region. In order to maintain the same luminous intensity, the voltage must be increased to drive more carrier transport. In the characteristic band, longer wavelengths require less band gaps, and the energy required for recombination is relatively lower. Consequently, the voltage change is more significantly affected by temperature. Reducing the thickness of the barrier layer 1071 as the emission wavelength increases can effectively control the voltage fluctuation of the components in low-temperature environments. In an embodiment, the maximum number of periods in the active layer 107 also decreases as the emission wavelength increases. That is, both the number of periods of the multiple quantum well structure and the thickness of the barrier layer 1071 decrease simultaneously as the emission wavelength increases, working together to optimize component performance.

In an optional embodiment, the characteristic band sequentially includes a first band and a second band from a lower wavelength to a higher wavelength. A critical wavelength value between the first band and the second band is located within a range of 620 nm to 630 nm. The difference of the thickness of the barrier layer 1071 corresponding to the second band is greater than the difference corresponding to the first band. For the band with longer wavelengths, the thickness of the barrier layer 1071s is further reduced to balance the HC performance and the production costs. In an embodiment, the critical wavelength value is 625 nm. That is, for light-emitting diodes with wavelengths above 625 nm, the thickness of the barrier layer 1071 decreases more significantly as the emission wavelength increases, so as to effectively mitigate the issue of low-temperature voltage increase while also reducing production costs. For light-emitting diodes with wavelengths below 625 nm, the thickness of the barrier layer 1071 does not need to be reduced excessively to balance the HC performance and the issue of low-temperature voltage increase. In an embodiment, the thickness of the well layer 1072 in the active layer 107 is in a range of 30 Å to 50 Å.

In an optional embodiment, a wavelength of the first band is less than or equal to 625 nm. In the first band, the thickness of the barrier layer 1071 is less than or equal to 100 Å, for example, 60 Å, 70 Å, 80 Å, or 90 Å. The thickness of the well layer 1072 is in a range of 30 Å to 50 Å, for example, 35 Å, 40 Å, or 45 Å. In an embodiment, the thickness of the barrier layer 1071 is in a range of 70 Å to 90 Å, and the thickness of the well layer 1072 is 40 Å. For the light-emitting diodes with shorter emission wavelengths within the characteristic band, the decrease in operating temperature has a relatively smaller impact on carrier mobility, and the resulting voltage increase is also relatively smaller. Appropriately setting the thickness of the barrier layer 1071 can balance the HC performance and the low-temperature voltage issues. Concurrently, the number of periods in the active layer 107 can be controlled to further optimize product performance.

In an optional embodiment, a wavelength of the second band is greater than or equal to 625 nm. In the second band, the thickness of the barrier layer 1071 is less than or equal to 70 Å, for example, 50 Å, 60 Å, or 70 Å. The thickness of the well layer 1072 is in a range of 30 Å to 50 Å, for example, 35 Å, 40 Å, or 45 Å. In an embodiment, the thickness of the barrier layer 1071 is in a range of 60 Å to 70 Å, and the thickness of the well layer 1072 is 40 Å. For the light-emitting diodes with longer emission wavelengths within the characteristic band, the decrease in operating temperature has a more pronounced impact on carrier mobility, and the resulting voltage increase is also relatively larger. In practical use, the operating voltage in a -40°C environment can be more than 10% higher than the voltage at room temperature, or the actual difference can exceed 0.2 V. Reducing the thickness of the barrier layer 1071 as much as possible, to 80 Å or even below 60 Å, which helps balance HC performance and the issue of low-temperature voltage increase. Concurrently, the number of periods in the active layer 107 is controlled and also significantly reduced. Together, these measures ensure a sufficient number of carriers recombine in the well layer 1072s, thereby maintaining product brightness and further optimizing product performance.

As an example, for light-emitting diodes with wavelengths of 605 nm, 615 nm, 625 nm, and 635 nm, the thicknesses of their barrier layer 1071s can be set to 90 Å, 85 Å, 80 Å, and 60 Å, respectively.

### Embodiment 3

The embodiment provides a light-emitting diode, at least including a semiconductor stack layer. The semiconductor stack layer has a first surface 112 and a second surface 113 opposite to each other, and the semiconductor stack layer includes a first semiconductor layer, an active layer 107 and a second semiconductor layer sequentially stacked in that order from the first surface 112 to the second surface 113. The active layer 107 includes a multiple quantum well structure with multiple periods, and each period of the multiple quantum well structure includes a well layer 1072 and a barrier layer 1071 sequentially stacked in that order. An emission wavelength of the light-emitting diode is in a range of 600 nm to 730 nm, a number of periods of the multiple quantum well structure in the active layer 107 is in a range of 5 and 25, and a thickness of the barrier layer 1071 is less than or equal to 100 Å. The barrier layer 1071 includes an Al component, and a content of the Al component in the barrier layer 1071 is in a range of 30% and 100%. In an embodiment, the number of periods of the multiple quantum well structure in the active layer 107 is in a range of 7 and 22, the thickness of the barrier layer 1071 is in a range of 60 Å and 90 Å, the content of the Al component in the barrier layer 1071 is in a range of 55% to 75%, and the emission wavelength of the light-emitting diode is in a range of 625 nm to 635 nm. The light-emitting diode represents an optimal design for balancing HC performance and low-temperature voltage stability, which effectively solves the problem of excessive voltage difference between low temperature and room temperature for devices in the band.

In an optional embodiment, the emission wavelength of the light-emitting diode is in a range of 615 nm to 625 nm. The number of periods of the multiple quantum well structure in the active layer 107 is in a range of 15 to 22, and the thickness of the barrier layer 1071 is in a range of 70 Å to 90 Å. In an embodiment, the content of the Al component in the barrier layer 1071 is in a range of 65% to 75%. For products with emission bands in a range of 615 nm to 625 nm, the multiple quantum well structure provided by the technical solution can effectively balance HC performance and low-temperature voltage issues. Setting the thickness of the barrier layer 1071 to 70 Å to 90 Å and the content of the Al component between 65% and 75% further optimizes product performance and wavelength stability.

In an optional embodiment, the emission wavelength of the light-emitting diode is in a range of 625 nm to 635 nm. The number of periods of the multiple quantum well structure in the active layer 107 is in a range of 7 to 12, and the thickness of the barrier layer 1071 is in a range of 60 Å to 70 Å. In an embodiment, the content of the Al component in the barrier layer 1071s is in a range of 55% to 65%. For products with emission bands in a range of 625 nm to 635 nm, the multiple quantum well structure provided by the technical solution can effectively balance HC performance and low-temperature voltage issues. Setting the thickness of the barrier layer 1071 to 60 Å to 70 Å further optimizes product performance and wavelength stability.

### Embodiment 4

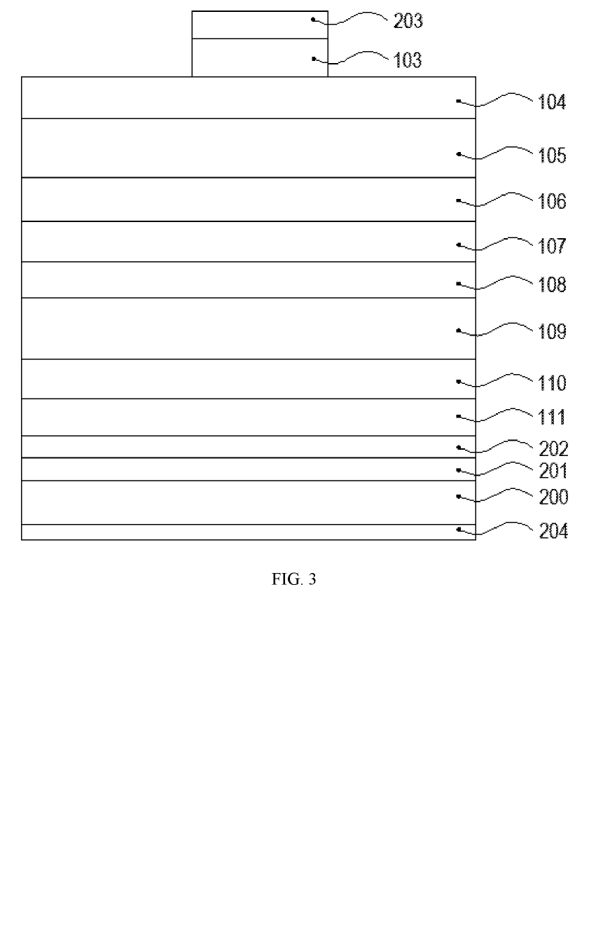

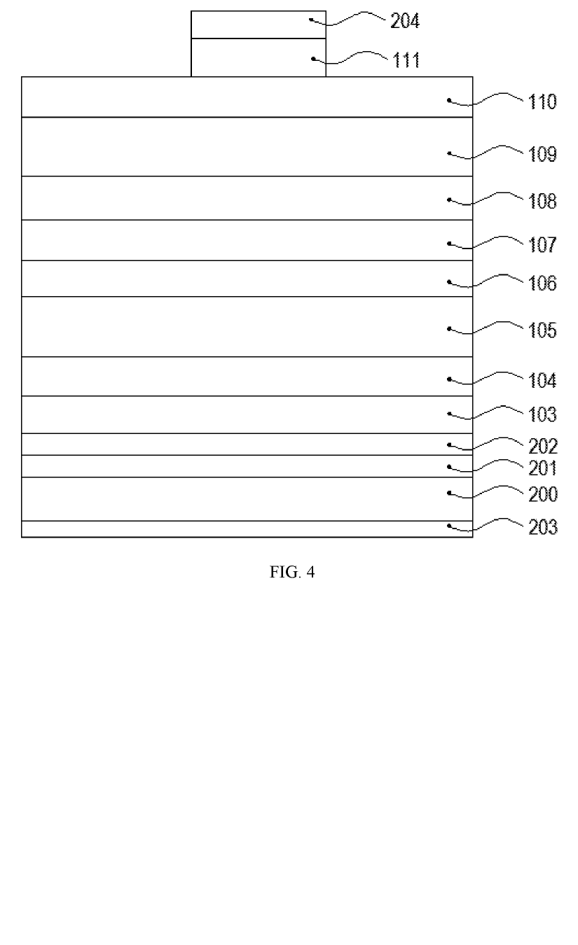

Referring to FIG. 3, the embodiment provides a light-emitting diode. The light-emitting diode of the embodiment adopts the epitaxial structure shown in FIG. 1 and further includes a first electrode 203 and a second electrode 204, and the first electrode 203 and the second electrode 204 are electrically connected to the first semiconductor layer and the second semiconductor layer, respectively.

The light-emitting diode includes a substrate 200. The semiconductor stack layer is bonded to the substrate 200 through a bonding layer 201. The semiconductor stack layer includes a second ohmic contact layer 111, a second current spreading layer 110, a second covering layer 109, a second spacer layer 108, the active layer 107, a first spacer layer 106, a first covering layer 105, a first current spreading layer 104, and a first ohmic contact layer 103 sequentially stacked on the substrate 200 in that order.

In an optional embodiment, the substrate 200 is a conductive substrate. The conductive substrate can be silicon, silicon carbide, or a metal substrate. The metal substrate is a copper substrate, a tungsten substrate, or a molybdenum substrate. In order to sufficiently support the semiconductor stack layer with mechanical strength, a thickness of the substrate 200 is 50 microns (μm) or more. In an embodiment, in order to facilitate mechanical processing of the substrate 200 after bonding to the semiconductor stack layer, the thickness of the substrate 200 does not exceed 300 μm. In the embodiment, the substrate 200 is a silicon substrate.

The first electrode 203 is disposed on the first ohmic contact layer 103. The first electrode 203 is in ohmic contact with the first ohmic contact layer 103 to enable current flow. A reflective layer 202 may be disposed between the semiconductor stack layer and the substrate 200. The reflective layer 202 includes an ohmic contact metal layer and a dielectric material layer. The ohmic contact metal layer and the dielectric material layer work together to form an ohmic contact with the first ohmic contact layer 103 on one hand, and on the other hand, to reflect light beams emitted from the active layer 107 towards the light-emitting surface of the first current spreading layer 104 or the sidewalls of the semiconductor stack layer for light extraction.

The light-emitting diode further includes a second electrode 204. The second electrode 204 is located on a back surface of the substrate 200. Alternatively, the second electrode 204 may be located on a same side as the semiconductor stack layer on the substrate 200. The first electrode 203 and the second electrode 204 include a transparent conductive material and/or a metal material. The transparent conductive material includes a transparent conductive layer, such as indium tin oxide (ITO) or indium zinc oxide (IZO). The metal material includes at least one of germanium gold nickel (GeAuNi), gold germanium (AuGe), gold zinc (AuZn), gold (Au), Al, platinum (Pt), and titanium (Ti).

### Embodiment 5

Referring to FIG. 4, the embodiment provides a light-emitting diode. The light-emitting diode of the embodiment adopts the epitaxial structure shown in FIG. 1 and further includes a first electrode 203 and a second electrode 204, and the first electrode 203 and the second electrode 204 are electrically connected to the first semiconductor layer and the second semiconductor layer, respectively. Descriptions of parts that are the same as or similar to those in the embodiment 4 are omitted here. The difference from the embodiment 4 is as follows.

The light-emitting diode includes a substrate 200. The semiconductor stack layer is bonded to the substrate 200 through a bonding layer 201. The semiconductor stack a first ohmic contact layer 103, a first current spreading layer 104, a first cladding layer 105, a first spacer layer 106, the active layer 107, a second spacer layer 108, a second cladding layer 109, a second current spreading layer 110, and a second ohmic contact layer 111 sequentially stacked on the substrate 200 in that order.

In an optional embodiment, the substrate 200 is a conductive substrate. In an embodiment, the substrate 200 is a copper substrate.

The second electrode 204 is disposed on the second ohmic contact layer 111. The first electrode 203 is in ohmic contact with the first ohmic contact layer 103 to enable current flow. The light-emitting diode further includes a first electrode 203 located on a back surface of the substrate 200. Alternatively, the first electrode 203 may be located on a same side as the semiconductor stack layer on the substrate 200.

### Embodiment 6

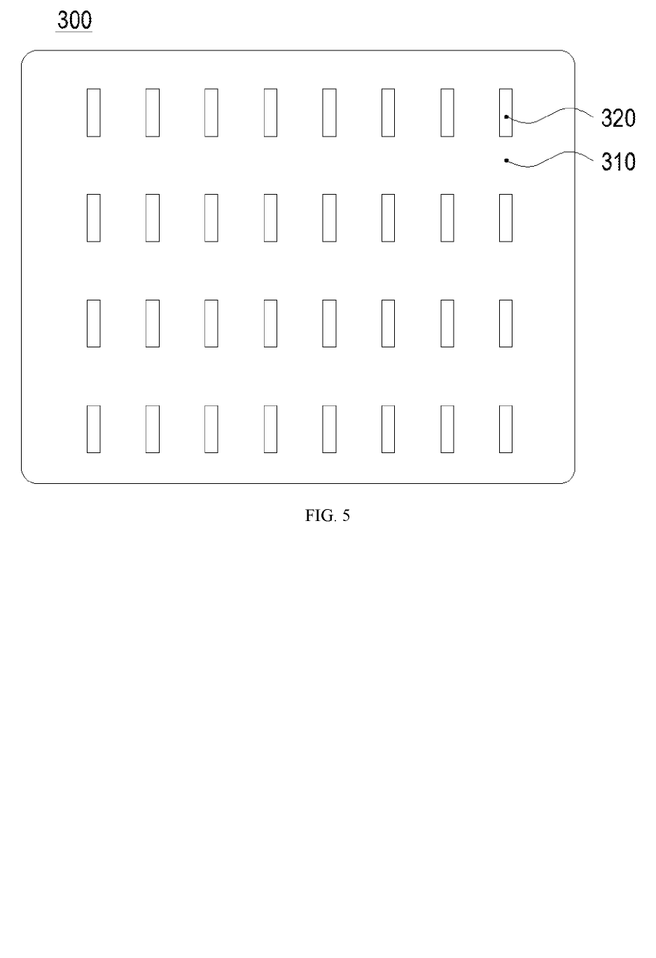

Referring to FIG. 5, the embodiment provides a light-emitting device 300, including a circuit board 310 and multiple light-emitting sources 320 arranged in an array. A drive circuit is disposed in the circuit board 310, and the light-emitting sources 320 are electrically connected to the drive circuit to be controlled by the drive circuit for turning on or off. The light-emitting sources 320 are any one of the light-emitting diodes described in the embodiments 1 to 5. The light-emitting device 300 can be an automotive lamp, such as a brake light, turn signal, or ambient light, and can also be other lighting devices, such as a projector, stage light, or display screen. The light-emitting device provided in the embodiment exhibits excellent voltage stability in low-temperature environments. Under operating conditions of -20°C or even below -40°C, a difference of voltage of the light-emitting device 300 compared to its voltage under room temperature conditions is less than or equal to 10%, and tests show that the actual voltage difference in all cases does not exceed 0.2 V. The light-emitting device 300 and the light-emitting diodes provided in other embodiments of the disclosure can effectively balance HC performance and low-temperature voltage stability, thereby achieving good luminous brightness and product quality.

In conclusion, the light-emitting diode and the light-emitting device provided in the disclosure effectively overcome various shortcomings of the related art and possess high industrial utility value.

The foregoing embodiments are provided to illustratively explain principles and efficacy of the disclosure, and are not intended to limit the disclosure. Any those skilled in the art may modify or alter the aforementioned embodiments without departing from a spirit and a scope of the disclosure. Therefore, all equivalent modifications or variations made by those skilled in the art based on the disclosed spirit and technical concepts of the disclosure without departing from its essence shall still fall within a scope of the claims of the disclosure.

What is claimed is:

1. A light-emitting diode, at least comprising:
a semiconductor stack layer, having a first surface and a second surface opposite to each other, wherein the semiconductor stack layer comprises a first semiconductor layer, an active layer and a second semiconductor layer sequentially stacked in that order from the first surface to the second surface;
wherein the active layer comprises a multiple quantum well structure with a plurality of periods, and each of the plurality of periods of the multiple quantum well structure comprises a well layer and a barrier layer sequentially stacked in that order; and
wherein an emission wavelength of the light-emitting diode is in a range of 605 nanometers (nm) to 730 nm, a number of the plurality of periods of the multiple quantum well structure in the active layer is in a range of 5 to 25, and a thickness of the barrier layer is in a range of 50 angstroms (Å) to 100 Å.

2. The light-emitting diode as claimed in claim 1, wherein the barrier layer comprises an aluminum (Al) component, and a content of the Al component in the barrier layer is in a range of 30% to 100%.

3. The light-emitting diode as claimed in claim 2, wherein the number of the plurality of periods of the multiple quantum well structure in the active layer is in a range of 7 to 22, and the thickness of the barrier layer is in a range of 60 Å to 90 Å.

4. The light-emitting diode as claimed in claim 3, wherein the content of the Al component in the barrier layer is in a range of 55% to 75%.

5. The light-emitting diode as claimed in claim 1, wherein the emission wavelength of the light-emitting diode is less than or equal to 625 nm; and
the number of the plurality of periods of the multiple quantum well structure in the active layer is in a range of 8 to 25, and the thickness of the barrier layer is in a range of 70 Å to 100Å.

6. The light-emitting diode as claimed in claim 5, wherein the content of the Al component in the barrier layer is in a range of 50% to 100%.

7. The light-emitting diode as claimed in claim 5, wherein the emission wavelength of the light-emitting diode is in a range of 615 nm to 625 nm; and
the number of the plurality of periods of the multiple quantum well structure in the active layer is in a range of 15 to 22, and the thickness of the barrier layer is in a range of 70 Å to 90 Å.

8. The light-emitting diode as claimed in claim 7, wherein the content of the Al component in the barrier layer is in a range of 65% to 75%.

9. The light-emitting diode as claimed in claim 1, wherein the emission wavelength of the light-emitting diode is greater than or equal to 625 nm; and
the number of the plurality of periods of the multiple quantum well structure in the active layer is in a range of 5 to 15, and the thickness of the barrier layer is in a range of 50 Å to 80Å; and the content of the Al component in the barrier layer is in a range of 30% to 80%.

10. The light-emitting diode as claimed in claim 9, wherein the emission wavelength of the light-emitting diode is in a range of 625 nm to 635 nm; and
the number of the plurality of periods of the multiple quantum well structure in the active layer is in a range of 7 to 12, and the thickness of the barrier layer is in a range of 60 Å to 70 Å; and the content of the Al component in the barrier layer is in a range of 55% to 65%.

11. The light-emitting diode as claimed in claim 1, further comprising a first electrode and a second electrode, and the first electrode and the second electrode are electrically connected to the first semiconductor layer and the second semiconductor layer, respectively.

12. A light-emitting diode, at least comprising:
a semiconductor stack layer, having a first surface and a second surface opposite to each other, wherein the semiconductor stack layer comprises a first semiconductor layer, an active layer and a second semiconductor layer sequentially stacked in that order from the first surface to the second surface;
wherein the active layer comprises a multiple quantum well structure with a plurality of periods, and each of the plurality of periods of the multiple quantum well structure comprises a well layer and a barrier layer sequentially stacked in that order; and
wherein in a characteristic band, a maximum number of the plurality of periods of the multiple quantum well structure in the active layer decreases as an emission wavelength of the light-emitting diode increases, and a wavelength of the characteristic band is in a range of 605 nm to 730 nm.

13. The light-emitting diode as claimed in claim 12, wherein the maximum number of the plurality of periods of the multiple quantum well structure in the active layer varies in a non-arithmetic manner, and a differential in the maximum number of the plurality of periods of the multiple quantum well structure in the active layer increases as the emission wavelength of the light-emitting diode increases.

14. A light-emitting diode, at least comprising:
a semiconductor stack layer, having a first surface and a second surface opposite to each other, wherein the semiconductor stack layer comprises a first semiconductor layer, an active layer and a second semiconductor layer sequentially stacked in that order from the first surface to the second surface;
wherein the active layer comprises a multiple quantum well structure with a plurality of periods, and each of the plurality of periods of the multiple quantum well structure comprises a well layer and a barrier layer sequentially stacked in that order; and
wherein in a characteristic band, a thickness of the barrier layer decreases as an emission wavelength of the light-emitting diode increases, and a wavelength of the characteristic band is in a range of 605 nm to 730 nm.

15. The light-emitting diode as claimed in claim 14, wherein the characteristic band comprises a first band and a second band in sequence, and a critical wavelength value between the first band and the second band is located within a range of 620 nm to 630 nm; and
a differential in a maximum number of the plurality of periods of the multiple quantum well structure in the active layer in the second band is greater than a differential in a maximum number of the plurality of periods of the multiple quantum well structure in the active layer in the first band.

16. The light-emitting diode as claimed in claim 15, wherein a wavelength of the first band is less than or equal to 625 nm; and
in the first band, a number of the plurality of periods of the multiple quantum well structure in the active layer is in a range of 8 to 25, the thickness of the barrier layer is in a range of 70 Å to 100 Å, and a content of an Al component in the barrier layer is in a range of 50% to 100%.

17. The light-emitting diode as claimed in claim 15, wherein a wavelength of the second band is greater than or equal to 625 nm; and
in the second band, a number of the plurality of periods of the multiple quantum well structure in the active layer is in a range of 5 to 15, the thickness of the barrier layer is in a range of 50 Å to 80 Å, and a content of an Al component in the barrier layer is in a range of 30% to 80%.

18. The light-emitting diode as claimed in claim 14, wherein a thickness of each well layer in the active layer is in a range of 30 Å to 50 Å.

19. The light-emitting diode as claimed in claim 14, wherein a material of the barrier layer is Alₓ₁Ga_{y1}In₁₋_{x1-y1}P, a material of the well layer is Alₓ₂Ga_{y2}In₁₋_{x2-y2}P, where, 0≤x2<x1≤1, x1≥0.3, and 0≤y1<y2≤1.

20. A light-emitting device, comprising: a light-emitting source, wherein the light-emitting source is the light-emitting diode as claimed in claim 1.
